(19) United States
(12) Patent Application Publication
(10) Pub. No.: US 2023/0408551 A1
(43) Pub. Date: Dec. 21, 2023

(54) OSCILLOSCOPE HAVING A PRINCIPAL COMPONENT ANALYZER

(71) Applicant: Tektronix, Inc., Beaverton, OR (US)

(72) Inventor: Justin E. Patterson, Honolulu, HI (US)

(73) Assignee: Tektronix, Inc., Beaverton, OR (US)

(21) Appl. No.: 18/209,110

(22) Filed: Jun. 13, 2023

Related U.S. Application Data
(60) Provisional application No. 63/353,950, filed on Jun. 21, 2022.

(51) Int. Cl. G01R 13/02

(52) U.S. Cl. CPC G01R 13/029; G01R 13/0272

(57) ABSTRACT

A system includes an input for accepting an input signal from a Device Under Test (DUT), a measurement unit for generating first measurement data and second measurement data from the input signal, and one or more processors configured to derive at least one principal component from the first and second measurement data using principal component analysis, and remap the first measurement data and the second measurement data to a principal component domain derived from the at least one principal component. Methods of operation and description of storage media, the operation of which performs the above operations, are also described.

### CROSS-REFERENCE TO RELATED APPLICATIONS

This disclosure claims benefit of U.S. Provisional Application No. 63/353,950 titled “PRINCIPAL COMPONENT ANALYSIS AS AN OSCILLOSCOPE MEASUREMENT” filed on Jun. 21, 2022, the disclosure of which is incorporated herein by reference in its entirety.

### TECHNICAL FIELD

This disclosure relates to test and measurement instruments, and more particularly to measurement instruments that include a tool for performing principal component analysis on measurement data gathered by the instrument.

### BACKGROUND

Modern oscilloscopes and other test and measurement devices accept signals from a Device Under Test (DUT) and perform various measurements on these signals. In many cases data is also collected from the signals, and measurements and analysis may be performed on this collected data. Sometimes tests are performed on the measured parameters, such as threshold tests based on measured voltage, current, or power. And sometimes transformations of an input signal are performed prior to tests or measurements being carried out. For example, a test and measurement instrument may accept an input signal in the time domain, perform a Fourier Transform on the signal to convert it to the frequency domain, and then make the desired tests or measurements in the frequency domain.

As mentioned above, data may be collected from the input signal or, in some cases, the instrument may generate data that describes or characterizes the input signal. Although some conventional oscilloscopes may perform simple data processing on this data, such as statistical processing, or the data may be plotted using histograms or timing trends, in general, data analysis tools on conventional test and measurement devices are limited to simple tools and processes.

Embodiments according to the disclosure address these and other limitations found in conventional instruments.

### BRIEF DESCRIPTION OF THE DRAWINGS

FIG. 1 is a graph illustrating how an oscilloscope including principal component analysis applies such analysis to a collection of data gathered by the oscilloscope, according to embodiments of the disclosure.

FIG. 2 is a graph of a collection of data gathered by an oscilloscope having a principal component analyzer, according to embodiments of the disclosure.

FIGS. 3A and 3B are graphs of raw and sorted data samples showing the limitations of conventional data processing in present oscilloscopes.

FIG. 4A shows a set of histogram graphs illustrating how an oscilloscope including principal component analysis may apply a step of data analysis, according to embodiments of the disclosure.

FIG. 4B shows a set of histogram graphs illustrating how an oscilloscope including principal component analysis may apply another step of data analysis, according to embodiments of the disclosure.

FIGS. 5A and 5B are graphs illustrating how an oscilloscope including principal component analysis may apply additional steps of data analysis, according to embodiments of the disclosure.

FIG. 6 is a diagram illustrating re-generated data using only a single principal component, according to embodiments of the disclosure.

FIGS. 7A and 7B are time trend graphs illustrating how an oscilloscope including principal component analysis may present results of principal component analysis to a user, according to embodiments of the disclosure.

FIGS. 8A and 8B are spectrum graphs illustrating how an oscilloscope including principal component analysis may present results of principal component analysis to a user, according to embodiments of the disclosure.

FIG. 9 is a functional block diagram of an oscilloscope including principal component analysis, according to embodiments of the disclosure.

### DESCRIPTION

Embodiments of the invention include a test and measurement instrument, such as an oscilloscope, that is able to perform Principal Component Analysis (PCA) on measurements or data received by the instrument from a Device Under Test (DUT). PCA operates on large data sets, such as measurement data received from the DUT. Performing PCA on these data sets allows the user to determine which variables contain the most information about the data, such as measurements included in the data. In general, PCA is a matrix decomposition of the data that allows the user to analyze and extract insights from measurements in a principal component domain, which may be a different domain than the measurement domain that produced the measurement data. In some respects, the ability of PCA to re-map data from the measurement domain into a principal component domain is similar to a Fourier Transform recharacterizing data gathered, for instance in the time domain into measurements in the frequency domain. With PCA tools, the user may be able to discern relationships about particular measurements that were not recognizable without PCA analysis. Also, PCA analysis is particularly strong in analyzing multiple variables and determining which variables are correlated to one another.

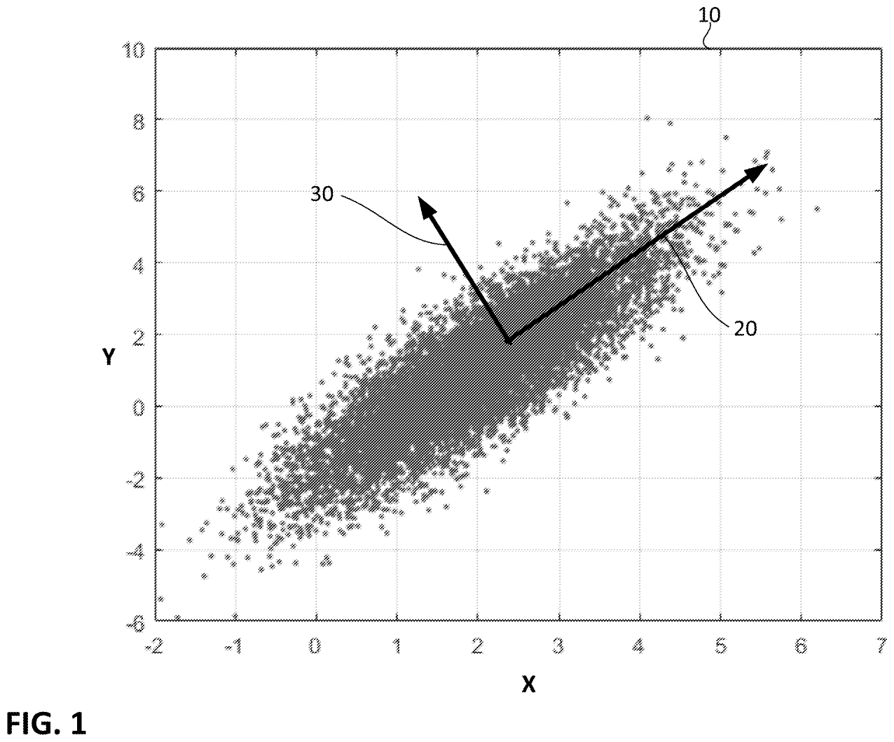

As mentioned above, PCA operates on sets of data. FIG. 1 is a chart 10 of data illustrating one of the basic fundamentals of PCA. Assume the data on the chart 10 is data that has an X component and a Y component. The data is mapped on chart 10 according to its XY components. PCA maps data from the measurement domain to a principal component domain through a coordinate transformation. To find the principal component axis, a Singular Value Decomposition is performed on the measurement data in a process described below. The principal component axis, in this case the axis 20, will always be the axis that has the maximum variance when the data from the dataset was projected onto that particular axis. To perform the Singular Value Decomposition on a set of data, one can envision generating an axis at an arbitrary orientation to the original data and projecting the dataset onto this arbitrary axis. The variance of the projected data for the present axis is recorded, and then the process repeats by projecting the original data to a new arbitrary axis. This process repeats through all possible axis orientations. When all possible axes have been produced, the variance data for each axis is analyzed to determine which axis has the largest variance when the original data was projected onto it. The axis that has the largest variance is the principal component axis. In other words, the principal component axis will point in the direction where the measurement data has the most variance. In the dataset of FIG. 1, the principal axis is labeled as axis 20. Other axes may be generated as well, one for each variable, or measurement in the data. In PCA, each of the principal axes is orthogonal to one another, so a secondary component axis 30 is orthogonal to the principal component axis 20, as illustrated in FIG. 1. PCA is particularly useful when measurements are linearly dependent, e.g., Feed-Forward Equalizer taps as well as data that is carried on a signal having various levels. It should be noted that visualization of measurement data, including visualizations that use PCA analysis, becomes increasingly difficult when the number of measurements is three or more, but is a useful tool for analyzing a more modest number of measurements. One of the reasons PCA is useful in analyzing measurement data is that PCA produces hierarchical results of principal components. Then, the user can systematically choose which principal components are to be used for statistical analysis or plotting.

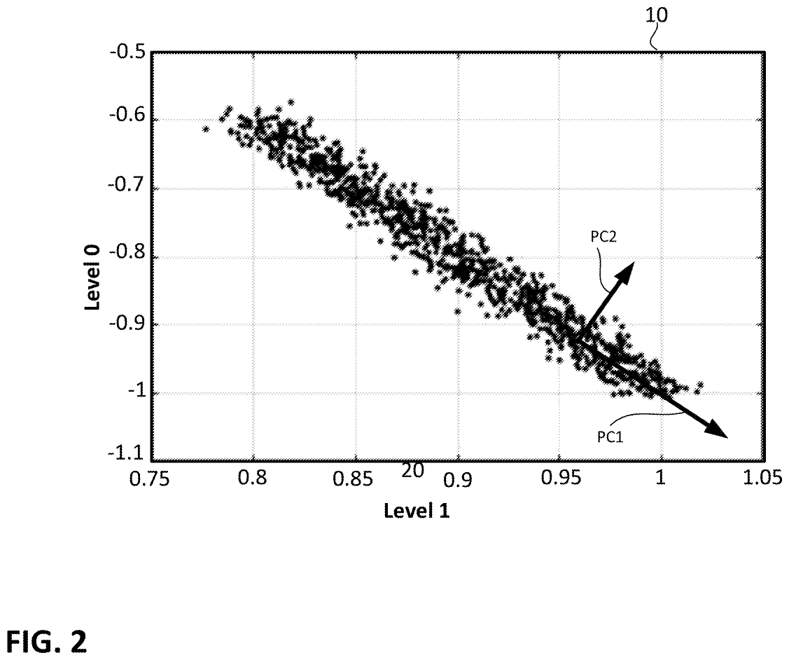

FIG. 2 illustrates measurement data gathered from a system with Non-Return-To-Zero coding having level measurements where the levels are linearly dependent. This data is generated with 1000 pairs of linearly dependent data. In other words, the recorded measurements simultaneously move in opposite directions from a mean, according to Equation 1.

lvl1=x₁+xₙ

lvl0=x₀+xₙ Equation (1)

where, x₁ is uniformly distributed in the interval [0.8, 1], x₀=−2x₁+1, and xₙ is zero-mean gaussian noise with standard deviation of 0.1.

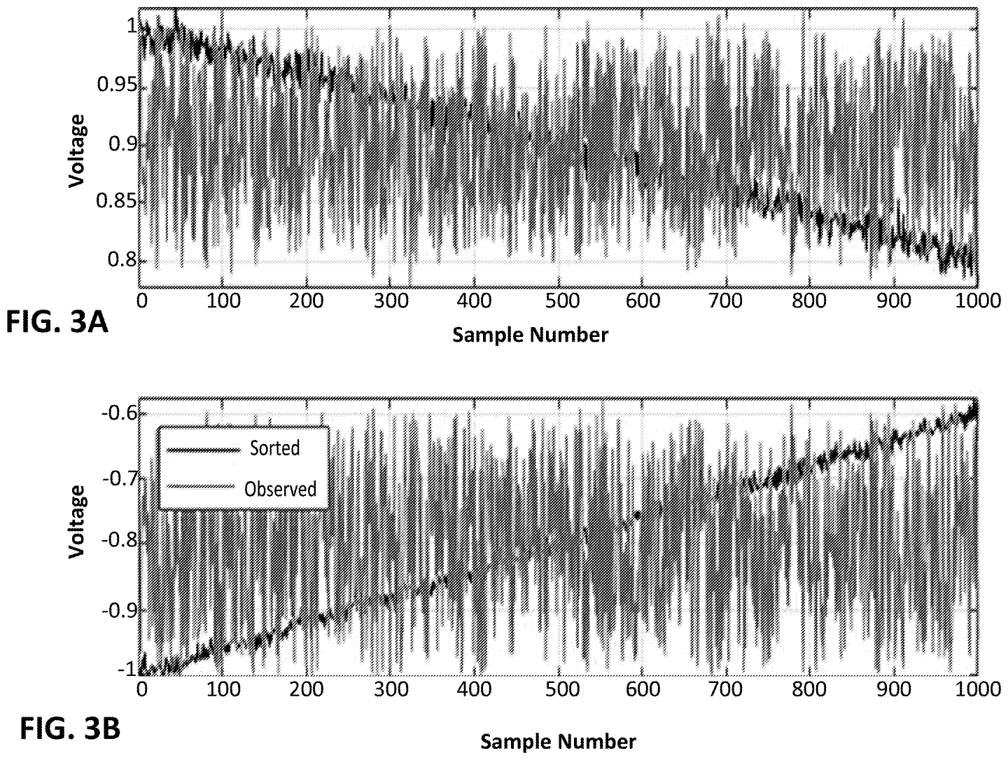

Traditional analysis of the measured data illustrated in FIG. 2 is illustrated in FIGS. 3A and 3B. Note that neither the instant measurements nor an observation trend of the measured levels reveals any significant information about the recorded data. In FIGS. 3A and 3B, the instant measurements are shown for each sample number, between 0-1000. A darker line, which is descending in FIG. 3A and ascending in FIG. 3B, shows the measurements in sorted order.

Using PCA on the recorded data, however, can reveal linear relationships within the data that are not recognizable using traditional tools, such as shown in FIGS. 3A and 3B.

First, to perform PCA, the principal components are extracted from the measurement data using Singular Value Decomposition to determine the primary component axis, described above. Then, after the principal components are derived, the measurements originally gathered in the measurement domain are projected into the Principal Component (PC) domain, where each PC is a linear combination of the levels.

$$[ \begin{matrix}P C 1 \\ P C 2\end{matrix} ] = [ \begin{matrix}- \text{.4446} & \text{.8957} \\ \text{.8957} & \text{.4446}\end{matrix} ] ( [ \begin{matrix}l v l 1 \\ l v l 0\end{matrix} ] - [ \begin{matrix}l v l 1 m e a n \\ l v l 0 m e a n\end{matrix} ] ) \qquad Equation ( 2 )$$

For example, using Equation 2, the levels [1, −1] V gets mapped to [−0.223, 0.0002].

The Principal Component 1 axis (PC1) and Principal Component 2 Axis (PC2) are illustrated in FIG. 2, which were determined by performing this PC analysis on the measurement data in FIG. 2. Note that the PC2 axis is orthogonal to the PC1 axis.

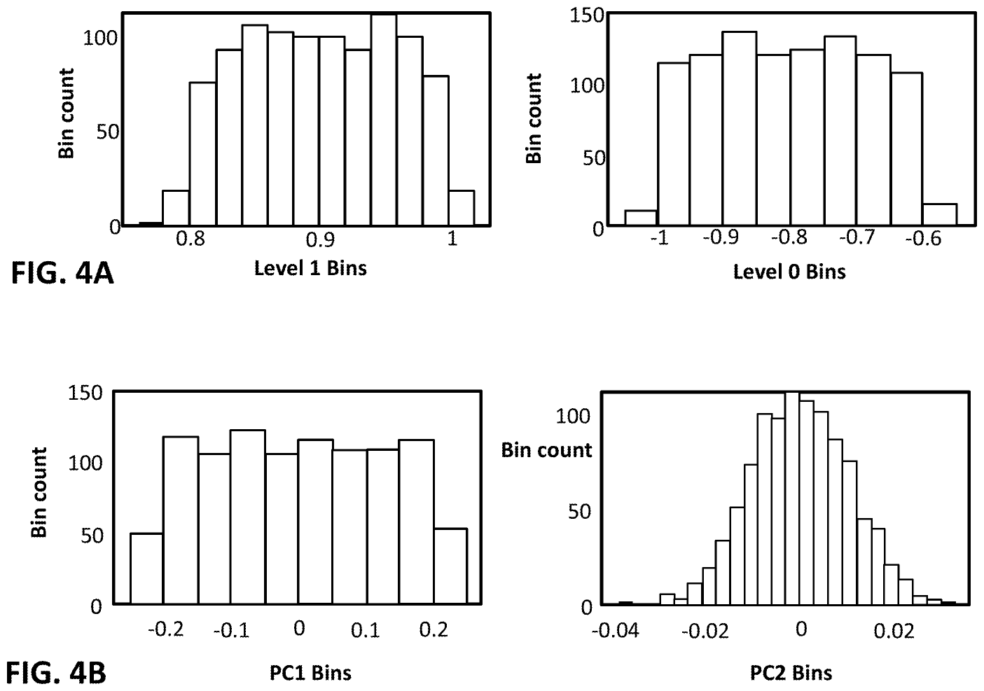

After the Principal components, and therefore the PC domain are derived, and after the original measurement data has also been projected into the PC domain, data analysis not possible with only the original data may proceed. For instance, measurement histograms may be generated that allow the user to investigate the behavior of the data being measured. FIG. 4A shows measurement histograms for the level 1 and level 0 data in the measurement domain, while FIG. 4B shows histograms for the measurement data after it has been projected onto the first two principal component domains, PC1 and PC2. FIG. 4B shows two separate histograms, one with the measurement data projected onto the first principal component, PC1, and divided into bins, while the other graph shows measurement data projected onto the second principal component, PC2, and divided into bins. Recall from above that PC2 is orthogonal to PC1.

Unlike the plots FIGS. 3A and 3B, which provided little information about the original measurement data, the histograms illustrated in FIG. 4B provides useful information about the measured data, such as patterns that are revealed when binning transformed data. The binning data for PC1 illustrates that most of the center bins have approximately the same measurements per bin, while the binning data for PC2 appears more like a Gaussian distribution.

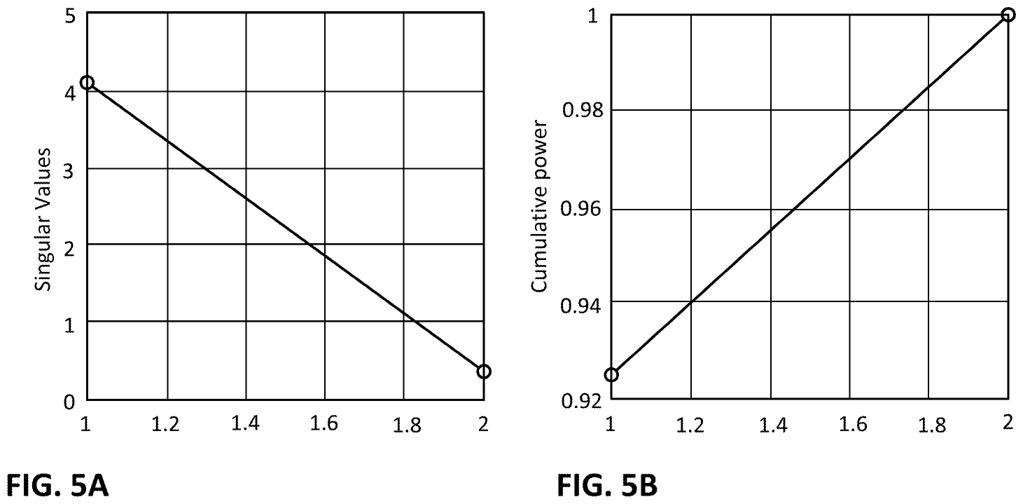

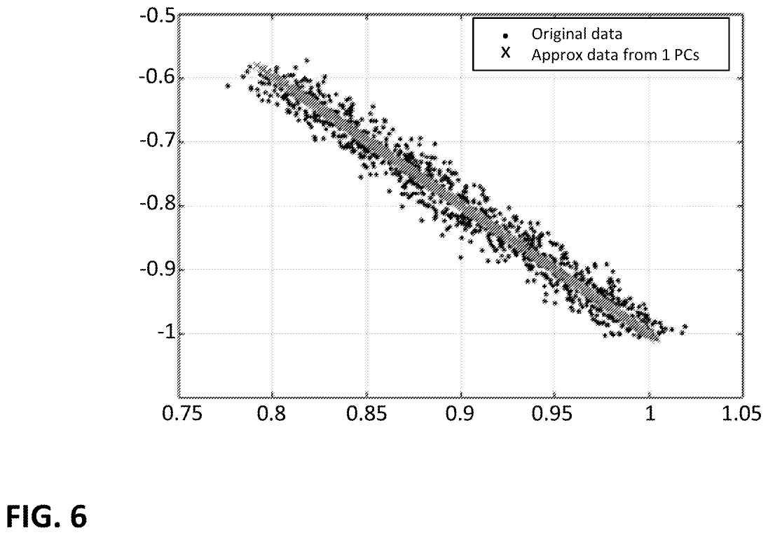

Further, the singular values mapped in FIGS. 5A and 5B reveal the power captured in the principal components. FIG. 5A plots the two singular values from the Sigma matrix, which is computed during the Singular Value Decomposition process. The Sigma matrix provides the variance, or standard deviation, along that PC axis. It may be thought of as “power” captured in that PC. FIG. 5B is a graph of normalized cumulative power or “energy”. The first data point in FIG. 5B has value of 0.92, which may be computed from the data graphed in FIG. 5A. In FIG. 5A, the total is 4.3. Then, the first data point in FIG. 5B for cumulative power is determined as the first value 4, divided by the total, 4.3, to yield approximately 0.92. The second data point in FIG. 5B for cumulative power is determined by adding the first and second values, 4+0.3, and dividing that total by the total, which is also 4.3, yielding 1.0, which is graphed as the second value in FIG. 5B. So, in this example 92% of the measurement variance is captured in the first PC, PC1. This means that the two measurements, i.e., the data originally mapped in FIG. 2 are linearly dependent to one another. The standard deviation of PC2 is exactly the standard deviation of the noise in Equation (1) above. Its relation to the singular values is σₙ=σ₂/\sqrt{N−1}=0.33/\sqrt{999}=0.01, where N is the number of observations. So, if the measurements are reconstructed from PC1 alone, this has the effect of removing the noise in observations, which is illustrated in FIG. 6.

Specifically, in FIG. 6, the original data is illustrated as many singular dots, while data that was reconstructed using only the PC1, and not the PC2 is illustrated as a much tighter collection of data. To produce the reconstructed data, the original measurement data was remapped into the PC domain, as described above. Then the contributions to the data from PC2 were removed, and the remaining data remapped, again, back to the measurement domain. Since noise is present in PC2, which can be observed by noticing the PC2 binning in FIG. 4B approximates a Gaussian curve, removing the PC2 component when remapping the data back from the PC domain to the original measurement domain eliminates this noise. Note how much more linear the reconstructed data in FIG. 6 appears compared to the original data.

In general, PCA is performed on a population of two or more measurements. The population can be from a single acquisition or multiple acquisitions. In this case, the user can query measurements through standard user interfaces of a test and measurement device, as described below.

If N measurements are configured in the global PCA measurement, then up to N PCs may be analyzed, but it is not strictly necessary that the same number of PCs must equal the number of measurements. For example,
1. MeasA (in the measurement domain)
2. MeasB (in the measurement domain)
3. MeasC (in the measurement domain)
4. PCA (configure to use MeasA and MeasB)
   a. PC1=V11*MeasA+V12*MeasB (in the PC domain)
   b. PC2=V21*MeasA+V22*MeasB (in the PC domain)

After the user has performed the PC1 and PC2 analysis, embodiments according to the disclosure allow the user to observe the PCA results through statistics and plots that are familiar to users of measurement devices. In this example, the measurement C remains in the measurement domain, which shows that not all of the measurements need be a part of the PCA. Instead, the user may use a combination of measurements made in the measurement domain and data analyzed in the PC domain for the overall analysis.

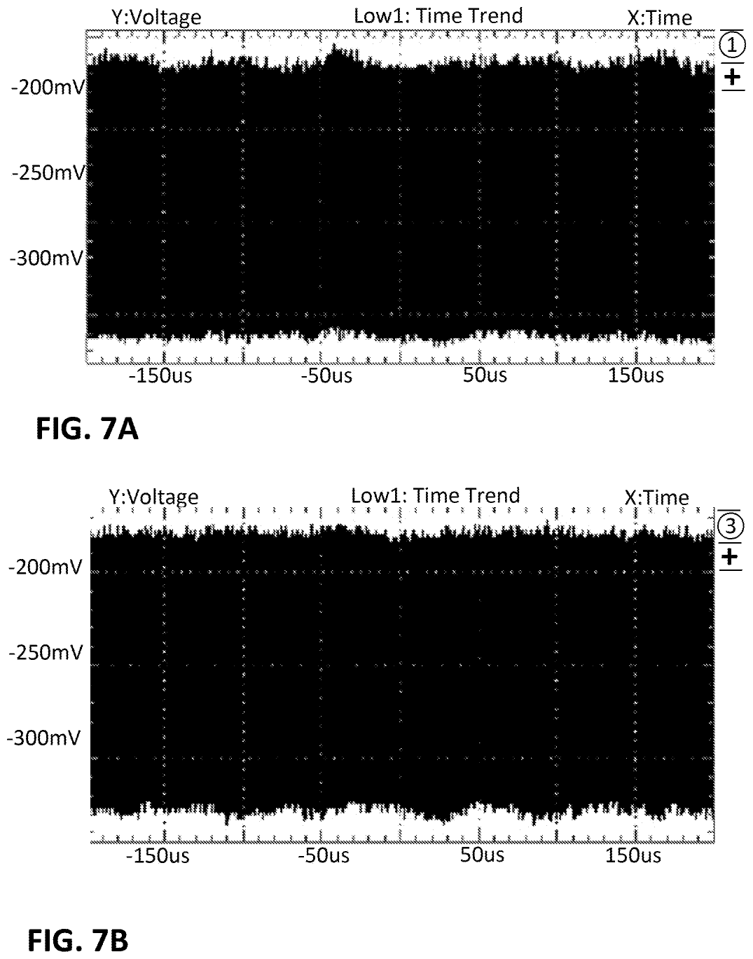

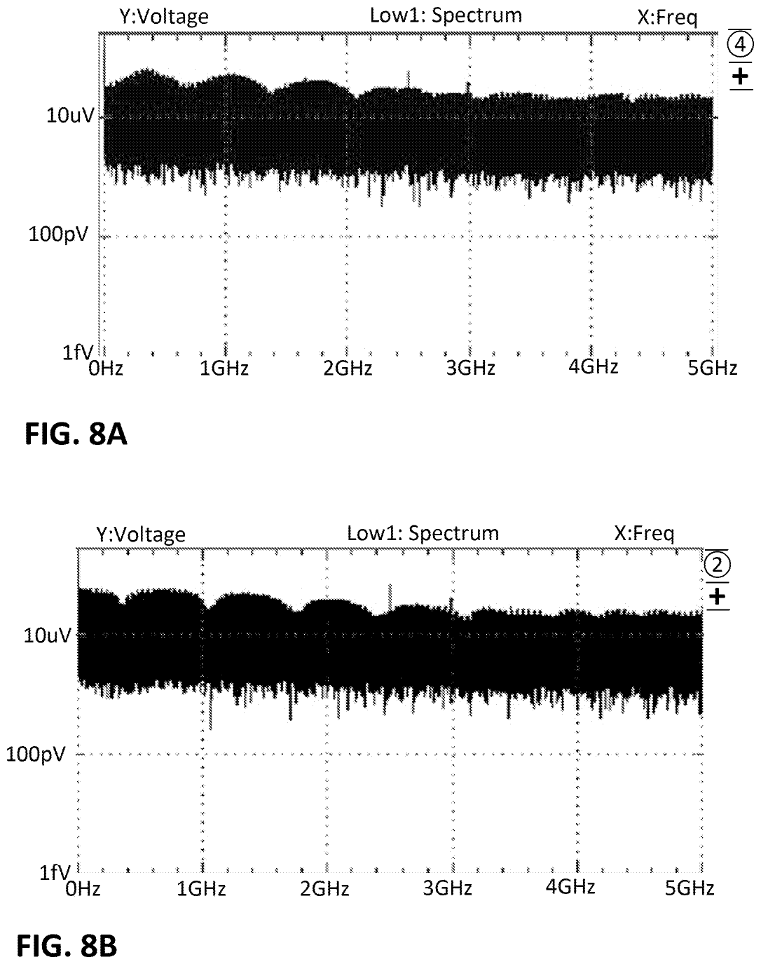

Statistics of PC1 and PC2 analysis may include statistical processing and results such as mean, standard deviation, as well as maximums and minimums. Plots showing PCA analysis may include typical plots users are familiar with, such as histograms, such as illustrated in FIG. 4B, time trend plots such as illustrated in FIGS. 7A and 7B, as well as spectrum plots such as shown in FIGS. 8A and 8B. In these figures the histograms of 4B are in the PC domain, while the time trend plots and spectrum plots are in the measurement domain, although the user may select any of the plots from either of the measurement domain or the PC domain for analysis and viewing.

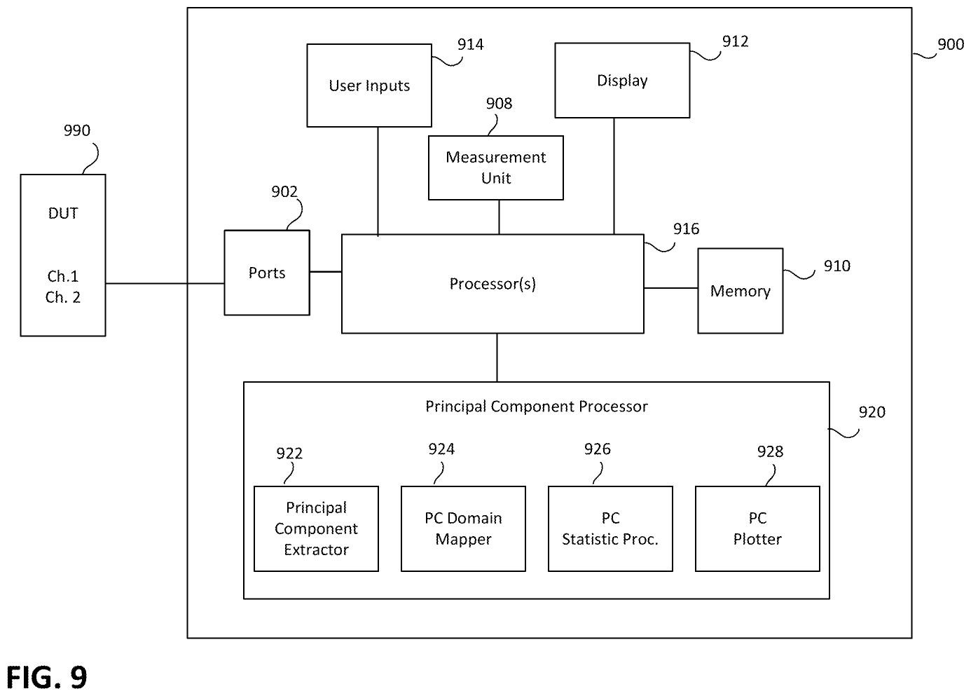

Embodiments of the disclosure operate on particular hardware and/or software to implement the above-described PCA operations. FIG. 9 is a block diagram of an example test and measurement instrument 900, such as an oscilloscope or spectrum analyzer for implementing embodiments of the disclosure disclosed herein. The test and measurement instrument 900 includes one or more ports 902, which may be any signaling medium. The ports 902 may include receivers, transmitters, and/or transceivers. Each port 902 is a channel of the test and measurement instrument 900. The ports 902 are coupled with one or more processors 916 to process the signals and/or waveforms received at the ports 902 from one or more devices under test (DUTs) 990. In some embodiments the ports accept multiple signals from the DUT 990, or from one or more DUTs. Although a two-signal DUT 990 is illustrated in FIG. 9, the test and measurement instrument 900 may accept any number of input signals up to the number of ports 902. Also, although only one processor 916 is shown in FIG. 9 for ease of illustration, as will be understood by one skilled in the art, multiple processors 916 of varying types may be used in combination in the instrument 900, rather than a single processor 916.

The ports 902 can also be connected to a measurement unit 908 in the test instrument 900. The measurement unit 908 can include any component capable of measuring aspects (e.g., voltage, amperage, amplitude, power, energy, etc.) of a signal received via ports 902. The test and measurement instrument 900 may include additional hardware and/or processors, such as conditioning circuits, analog to digital converters, and/or other circuitry to convert a received signal to a waveform for further analysis. The resulting waveform can then be stored in a memory 910, as well as displayed on a display 912.

The one or more processors 916 may be configured to execute instructions from the memory 910 and may perform any methods and/or associated steps indicated by such instructions, such as displaying and modifying the input signals received by the instrument. The memory 910 may be implemented as processor cache, random access memory (RAM), read only memory (ROM), solid state memory, hard disk drive(s), or any other memory type. The memory 910 acts as a medium for storing data, such as acquired sample waveforms, computer program products, and other instructions.

User inputs 914 are coupled to the processor 916. User inputs 914 may include a keyboard, mouse, touchscreen, and/or any other controls employable by a user to set up and control the instrument 900. User inputs 914 may include a graphical user interface or text/character interface operated in conjunction with the display 912. The user inputs 914 may receive remote commands or commands in programmatic form, either on the instrument 100 itself, or from a remote device. The display 912 may be a digital screen, a cathode ray tube-based display, or any other monitor to display waveforms, measurements, and other data to a user. While the components of test instrument 900 are depicted as being integrated within test and measurement instrument 900, it will be appreciated by a person of ordinary skill in the art that any of these components can be external to test instrument 900 and can be coupled to test instrument 900 in any conventional manner (e.g., wired and/or wireless communication media and/or mechanisms). For example, in some embodiments, the display 912 may be remote from the test and measurement instrument 900, or the instrument may be configured to send output to a remote device in addition to displaying it on the instrument 900. In further embodiments, output from the measurement instrument 900 may be sent to or stored in remote devices, such as cloud devices, that are accessible from other machines coupled to the cloud devices.

The instrument 900 may include a principal component processor 920, which may be a separate processor from the one or more processors 916 described above, or the functions of the principal component processor 920 may be integrated into the one or more processors 916. Additionally, the principal component processor 920 may include separate memory, use the memory 910 described above, or any other memory accessible by the instrument 900. The principal component processor 920 may include specialized processors or operations to implement the functions described above. For example, the principal component processor 920 may include a principal component extractor 922 used to perform principal component analysis on two or more sets of measurement data. The principal component processor 920 may perform the singular value decomposition process on the original data sets as described above. Then a PC domain mapper 924 may map the measurement data from the original measurement domain to the principal component domains derived by the principal component extractor 922. Once the measurement data has been mapped to the principal component domains, various statistics and plots may be generated on the remapped data. For example, a PC statistics processor 926 may generate statistical data derived from the remapped data, including mean, standard deviation, maximum and minimum processing. Further, a PC plotter 928 may generate histograms, time trend plots and spectrum diagrams that are helpful to the user in analyzing the measurement data.

Any or all of the components of the principal component processor 920, including the principal component extractor 922, PC domain mapper 924, PC statistics processor 926, and the PC plotter 928 may be embodied in one or more separate processors, and the separate functionality described herein may be implemented as specific pre-programmed operations of a special purpose or general purpose processor. Further, as stated above, any or all of the components or functionality of the principal component processor 920 may be integrated into the one or more processors 916 that operate the instrument 900.

Aspects of the disclosure may operate on a particularly created hardware, on firmware, digital signal processors, or on a specially programmed general-purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### Examples

Illustrative examples of the disclosed technologies are provided below. An embodiment of the technologies may include one or more, and any combination of, the examples described below.

Example 1 is a system, comprising an input for accepting an input signal from a Device Under Test (DUT), a measurement unit for generating first measurement data and second measurement data from the input signal, and one or more processors configured to derive at least one principal component from the first and second measurement data using principal component analysis, and remap the first measurement data and the second measurement data to a principal component domain derived from the at least one principal component.

Example 2 is a system according to Example 1, in which the one or more processors are further configured to perform statistical analysis on the remapped data.

Example 3 is a system according to any of the preceding Examples, in which the statistical analysis comprises mean and standard deviation analysis.

Example 4 is a system according to Example 2 or Example 3, in which the one or more processors are further configured to show a result of the statistical analysis on an output display.

Example 5 is a system according to any of the preceding Examples, in which the one or more processors are further configured to generate a plot from the remapped data and show the plot on an output display.

Example 6 is a system according to Example 5, in which the plot is a histogram, a time-trend plot, or a spectrum display.

Example 7 is a system according to any of the preceding Examples, in which the one or more processors are further configured to remap the first measurement data and the second measurement data from the principal component domain back to a measurement domain using information from only a single principal component.

Example 8 is a system according to any of the preceding Examples, in which the one or more processors are further configured to remap the first measurement data and the second measurement data from the principal component domain back to a measurement domain using information from less than all of the components in the principal component domain.

Example 9 is a system according to any of the preceding Example, in which N sets of measurement data are generated by the measurement unit, and in which the one or more processors are configured to derive M principal components from the N sets of measurement data, where M is a range [1, N].

Example 10 is a method, including receiving an input signal from a Device Under Test (DUT), generating first measurement data from the input signal, generating second measurement data from the input signal, deriving at least one principal component from the first and second measurement data using principal component analysis, and remapping the first measurement data and the second measurement data to a principal component domain derived from the at least one principal component.

Example 11 is a method according to Example 10, further comprising performing statistical analysis on the remapped data.

Example 12 is a method according to Example 11, in which the statistical analysis comprises mean and standard deviation analysis.

Example 13 is a method according to either Example 11 or Example 12, further comprising showing a result of the statistical analysis on an output display.

Example 14 is a method according to any of the preceding Example Methods further comprising generating a plot from the remapped data; and showing the plot on an output display.

Example 15 is a method according to Example 14, in which the plot is a histogram, a time-trend plot, or a spectrum display.

Example 16 is a method according to any of the preceding Example Methods further comprising remapping the first measurement data and the second measurement data from the principal component domain back to a measurement domain using information from only a single principal component.

Example 17 is a method according to any of the preceding Example Methods further comprising remapping the first measurement data and the second measurement data from the principal component domain back to a measurement domain using information from less than all of the components in the principal component domain.

Example 18 is a method according to any of the preceding Example Methods further comprising generating N sets of measurement data from the input signal, and deriving M principal components from the N sets of measurement data, where M is a range [1, N].

Example 19 is a non-transitory computer-readable storage medium storing one or more instructions, which, when executed by one or more processors of a computing device, cause the computing device to receive an input signal from a Device Under Test (DUT), generate first measurement data from the input signal, generate second measurement data from the input signal, derive at least one principal component from the first and second measurement data using principal component analysis, and remap the first measurement data and the second measurement data to a principal component domain derived from the at least one principal component.

Example 20 is a non-transitory computer-readable storage medium according to Example 19, wherein execution of the one or more instructions further causes the computing device to perform statistical analysis on the remapped data.

Example 21 is a non-transitory computer-readable storage medium according to any of the Examples 19-20, wherein execution of the one or more instructions further causes the computing device to remap the first measurement data and the second measurement data from the principal component domain back to a measurement domain using information from only a single principal component.

Example 22 is a non-transitory computer-readable storage medium according to any of the Examples 19-20, wherein execution of the one or more instructions further causes the computing device to remap the first measurement data and the second measurement data from the principal component domain back to a measurement domain using information from less than all of the components in the principal component domain.

The previously described versions of the disclosed subject matter have many advantages that were either described or would be apparent to a person of ordinary skill. Even so, these advantages or features are not required in all versions of the disclosed apparatus, systems, or methods.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

Although specific examples of the invention have been illustrated and described for purposes of illustration, it will be understood that various modifications may be made without departing from the spirit and scope of the invention. Accordingly, the invention should not be limited except as by the appended claims.

We claim:

1. A system, comprising:
an input for accepting an input signal from a Device Under Test (DUT);
a measurement unit for generating first measurement data and second measurement data from the input signal; and
one or more processors configured to:
derive at least one principal component from the first and second measurement data using principal component analysis, and
remap the first measurement data and the second measurement data to a principal component domain derived from the at least one principal component.

2. The system according to claim 1, in which the one or more processors are further configured to perform statistical analysis on the remapped data.

3. The system according to claim 2, in which the statistical analysis comprises mean and standard deviation analysis.

4. The system according to claim 2, in which the one or more processors are further configured to show a result of the statistical analysis on an output display.

5. The system according to claim 1, in which the one or more processors are further configured to generate a plot from the remapped data and show the plot on an output display.

6. The system according to claim 5, in which the plot is a histogram, a time-trend plot, or a spectrum display.

7. The system according to claim 1, in which the one or more processors are further configured to:
remap the first measurement data and the second measurement data from the principal component domain back to a measurement domain using information from only a single principal component.

8. The system according to claim 1, in which the one or more processors are further configured to:
remap the first measurement data and the second measurement data from the principal component domain back to a measurement domain using information from less than all of the components in the principal component domain.

9. The system according to claim 1, in which N sets of measurement data are generated by the measurement unit, and in which the one or more processors are configured to derive M principal components from the N sets of measurement data, where M is a range [1, N].

10. A method, comprising:
receiving an input signal from a Device Under Test (DUT);
generating first measurement data from the input signal;
generating second measurement data from the input signal;
deriving at least one principal component from the first and second measurement data using principal component analysis; and
remapping the first measurement data and the second measurement data to a principal component domain derived from the at least one principal component.

11. The method of claim 10, further comprising performing statistical analysis on the remapped data.

12. The method of claim 11, in which the statistical analysis comprises mean and standard deviation analysis.

13. The method of claim 11, further comprising showing a result of the statistical analysis on an output display.

14. The method of claim 10, further comprising:
generating a plot from the remapped data; and
showing the plot on an output display.

15. The method of claim 14, in which the plot is a histogram, a time-trend plot, or a spectrum display.

16. The method of claim 10, further comprising remapping the first measurement data and the second measurement data from the principal component domain back to a measurement domain using information from only a single principal component.

17. The method of claim 10, further comprising remapping the first measurement data and the second measurement data from the principal component domain back to a measurement domain using information from less than all of the components in the principal component domain.

18. The method of claim 10, further comprising:
generating N sets of measurement data from the input signal; and
deriving M principal components from the N sets of measurement data, where M is a range [1, N].

19. A non-transitory computer-readable storage medium storing one or more instructions, which, when executed by one or more processors of a computing device, cause the computing device to:
receive an input signal from a Device Under Test (DUT);
generate N sets of measurement data from the input signal;
derive M principal components from the N sets of measurement data using principal component analysis, where M is a range [1, N]; and
remap the first measurement data and the second measurement data to a principal component domain derived from the M principal components.

20. The non-transitory computer-readable storage medium according to claim 19, wherein execution of the one or more instructions further causes the computing device to:
perform statistical analysis on the remapped data.

21. The non-transitory computer-readable storage medium according to claim 19, wherein execution of the one or more instructions further causes the computing device to remap at least one set of measurement data from the principal component domain back to a measurement domain using information from only a single principal component.

22. The non-transitory computer-readable storage medium according to claim 19, wherein execution of the one or more instructions further causes the computing device to remap at least one set of measurement data from the principal component domain back to a measurement domain using information from less than all of the components in the principal component domain.
